(19) United States
(12) Patent Application Publication
(10) Pub. No.: US 2025/0015065 A1
(43) Pub. Date: Jan. 9, 2025

(54) SEMICONDUCTOR PACKAGE

(71) Applicant: Samsung Electronics Co., Ltd., Suwon-si (KR)

(72) Inventor: Myungsam KANG, Suwon-si (KR)

(73) Assignee: Samsung Electronics Co., Ltd., Suwon-si (KR)

(21) Appl. No.: 18/425,332

(22) Filed: Jan. 29, 2024

(30) Foreign Application Priority Data
Jul. 6, 2023 (KR) 10-2023-0087446

(51) Int. Cl. H01L 25/16; H01L 23/00; H01L 23/498

(52) U.S. Cl. CPC H01L 25/162; H01L 23/49816; H01L 23/49833; H01L 23/49838; H01L 24/08; H01L 24/16; H01L 25/165; H01L 28/10; H01L 2224/08145; H01L 2224/16227; H01L 2224/16238; H01L 2924/1427; H01L 2924/15153; H01L 2924/182; H01L 2924/19011; H01L 2924/19042

(57) ABSTRACT

A semiconductor package includes a wiring structure including at least one first wiring layer and at least one first insulating layer, a semiconductor chip overlapping the wiring structure in a vertical direction, a second insulating layer overlapping the wiring structure in the vertical direction and including a cavity, an inductor in the cavity and electrically connected to the semiconductor chip, a lead-out pillar extending from one surface of the inductor facing the wiring structure and electrically connecting the inductor and the semiconductor chip, and an encapsulant encapsulating the inductor, wherein the inductor includes an insulating body and a coil portion in the insulating body, and configured to output a magnetic field in a direction, different from the vertical direction, and a region on one surface of the insulating body not overlapping the lead-out pillar is in direct contact with the encapsulant or the at least one first insulating layer.

### CROSS-REFERENCE TO RELATED APPLICATION(S)

This application claims benefit of priority to Korean Patent Application No. 10-2023-0087446 filed on Jul. 6, 2023 in the Korean Intellectual Property Office, the disclosure of which is incorporated herein by reference in its entirety.

### BACKGROUND

The present inventive concepts relate to semiconductor packages.

As electronic devices have a lighter weight and higher performance, miniaturization and higher performance in the semiconductor package field are also required. Performance of a semiconductor chip may be improved by inductance and characteristics thereof provided from an outside of the semiconductor chip into the semiconductor chip, but difficulty in miniaturizing a semiconductor package using inductance outside of the semiconductor chip may be higher than difficulty in miniaturizing a semiconductor package that does not use inductance outside of the semiconductor chip.

### SUMMARY

An aspect of the present inventive concepts is to provide a semiconductor package capable of efficiently using inductance outside of a semiconductor chip.

According to an aspect of the present inventive concepts, a semiconductor package may include a wiring structure having an alternating structure of at least one first wiring layer and at least one first insulating layer, a semiconductor chip overlapping the wiring structure in a stacking direction of the wiring structure, a second insulating layer overlapping the wiring structure in the stacking direction of the wiring structure and including a cavity, an inductor in the cavity and electrically connected to the semiconductor chip, a lead-out pillar extending from one surface of the inductor facing the wiring structure, and electrically connecting the inductor and the semiconductor chip, and an encapsulant encapsulating the inductor, wherein the inductor includes an insulating body and a coil portion disposed in the insulating body, the coil portion configured to output a magnetic field in a direction, different from the stacking direction of the wiring structure, and wherein a first region on one surface of the insulating body facing the wiring structure and not overlapping the lead-out pillar is in direct contact with the encapsulant or the at least one first insulating layer.

According to an aspect of the present inventive concepts, a semiconductor package may include a wiring structure having an alternating structure of at least one first wiring layer and at least one first insulating layer, a semiconductor chip overlapping the wiring structure in a stacking direction of the wiring structure, a second insulating layer overlapping the wiring structure in the stacking direction of the wiring structure and including a cavity, an inductor in the cavity and electrically connected to the semiconductor chip, and a lead-out pillar extending from one surface of the inductor facing the wiring structure and electrically connecting the inductor and the semiconductor chip, wherein the inductor includes an insulating body and a coil portion in the insulating body, wherein the insulating body has a first surface and a second surface facing the wiring structure and opposing each other, a third surface and a fourth surface facing the second insulating layer and opposing each other, and a fifth surface and a sixth surface facing the second insulating layer and opposing each other, and wherein a distance (Z1) between the first and second surfaces is greater than a distance (Y1) between the third and fourth surfaces, is greater than a distance (X1) between the fifth and sixth surfaces, and is greater than a thickness (Z2) of the second insulating layer.

According to an aspect of the present inventive concepts, a semiconductor package may include a wiring structure having an alternating structure of at least one first wiring layer and at least one first insulating layer, a semiconductor chip overlapping the wiring structure in a stacking direction of the wiring structure, a second insulating layer overlapping the wiring structure in the stacking direction of the wiring structure and including a cavity, an inductor in the cavity and electrically connected to the semiconductor chip, a lead-out pillar extending from one surface of the inductor facing the wiring structure and electrically connecting the inductor and the semiconductor chip, an additional lead-out pillar extending from the other surface of an insulating body of the inductor opposing the one surface of the insulating body of the inductor, and an encapsulant encapsulating the inductor, wherein the inductor includes the insulating body, and a coil portion in the insulating body, the coil portion configured to output a magnetic field in a direction, different from the stacking direction of the wiring structure, the at least one first wiring layer includes a plurality of first wiring layers, the at least one first insulating layer includes a plurality of first insulating layers, a first portion of the lead-out pillar and a first portion of the additional lead-out pillar pass through a portion of the encapsulant, a second portion of the lead-out pillar and a second portion of the additional lead-out pillar pass through upper and lower portions of the plurality of first insulating layers, respectively, the first portion of the lead-out pillar and the first portion of the additional lead-out pillar being different from the second portion of the lead-out pillar and the second portion of the additional lead-out pillar, respectively, and the lead-out pillar and the additional lead-out pillar extend in opposite directions at positions laterally offset from centers of the one surface and the other surface of the insulating body, respectively.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a cross-sectional view illustrating a semiconductor package according to an example embodiment.

FIGS. 2A and 2B are cross-sectional views illustrating an inductor disposed in a semiconductor package according to an example embodiment.

FIG. 3 is a view illustrating an equivalent circuit of a semiconductor package according to an example embodiment.

FIGS. 4A and 4B are cross-sectional views illustrating a method of manufacturing a semiconductor package according to an example embodiment.

FIG. 5 is a cross-sectional view illustrating a semiconductor package according to an example embodiment.

FIG. 6 is a cross-sectional view illustrating a semiconductor package according to an example embodiment.

FIG. 7 is a cross-sectional view illustrating a semiconductor package according to an example embodiment.

FIG. 8 is a cross-sectional view illustrating a semiconductor package according to an example embodiment.

FIG. 9 is a cross-sectional view illustrating a semiconductor package according to an example embodiment.

FIG. 10 is a cross-sectional view illustrating a semiconductor package according to an example embodiment.

FIG. 11 is a cross-sectional view illustrating a semiconductor package according to an example embodiment.

### DETAILED DESCRIPTION

The detailed description of the present inventive concepts refers to the accompanying drawings which, by way of example, illustrate specific example embodiments in which the present inventive concepts may be practiced. These example embodiments are described in sufficient detail to enable one skilled in the art to practice the present inventive concepts. It should be understood that the various example embodiments of the present inventive concepts are different from each other but are not necessarily mutually exclusive. For example, one example embodiment of specific shapes, structures, and characteristics described herein may be implemented in another example embodiment without departing from the spirit and scope of the present inventive concepts. Additionally, it should be understood that the location or arrangement of individual components within each disclosed example embodiment may be changed without departing from the spirit and scope of the present inventive concepts. Accordingly, the detailed description set forth below is not intended to be taken in a limiting sense, and the scope of the present inventive concepts is limited or defined only by the appended claims, with all equivalents as claimed by those claims. Like reference numbers in the drawings indicate the same or similar functions throughout the various aspects.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

Hereinafter, some example embodiments of the present inventive concepts will be described in detail with reference to the accompanying drawings such that those skilled in the art may easily practice the present inventive concepts.

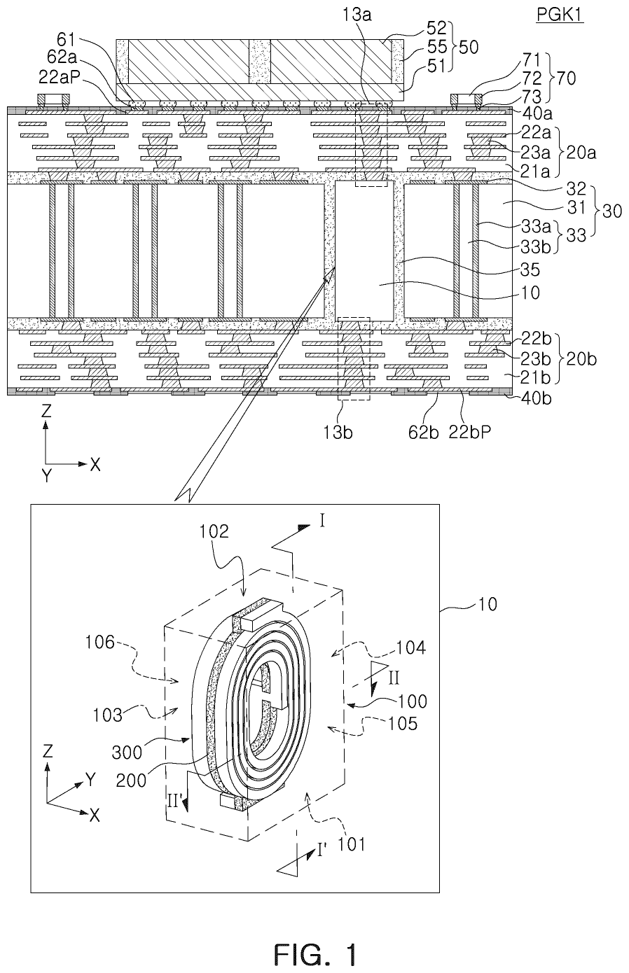

FIGS. 1, 5, 6, 7, 8, 9, 10, and 11 are cross-sectional views illustrating cross-sections of semiconductor packages PGK1, PGK2, PGK3, PGK4, PGK5, PGK6, PGK7, and PGK8 according to some example embodiments, taken along on an X-Z plane. For example, a semiconductor package (PGK1, PGK2, PGK3, PGK4, PGK5, PGK6, PGK7, and PGK8) may be a system in package (SIP) including two or more semiconductor chips, and may be at least portion of a package on package (POP) structure.

Referring to FIG. 1, a semiconductor package PGK1 according to an example embodiment may include a wiring structure (20a and 20b), a semiconductor chip 52, a second insulating layer 31, an inductor 10, a lead-out pillar 13a, and an encapsulant 35.

The wiring structure (20a and 20b) may have a structure in which at least one first wiring layer (22a and/or 22b) and at least one first insulating layer (21a and/or 21b) are alternately stacked. For example, the at least one first wiring layer (22a and/or 22b) may be provided as a plurality of first wiring layers (22a and/or 22b) overlapping each other in a stacking direction (e.g., Z-direction), and the at least one first insulating layer (21a and/or 21b) may be provided as a plurality of first insulating layers (21a and/or 21b) overlapping each other in the stacking direction (e.g., Z-direction). The plurality of first wiring layers (22a and 22b) and the plurality of first insulating layers (21a and 21b) may be alternately stacked one layer at a time. The wiring structure (20a and 20b) may further include wiring vias 23a and 23b connected to the at least one first wiring layer (22a and 22b) and passing through the at least one first insulating layer (21a and 21b). The wiring vias 23a and 23b may be interlayer electrical connection paths of the plurality of first wiring layers (22a and 22b). For example, the wiring structure (20a and 20b) may be at least a portion of a printed circuit board.

At least one first insulating layer (21a and 21b) may include an insulating material, and may include, for example, a thermosetting resin such as an epoxy resin or a thermoplastic resin such as polyimide. For example, the at least one first insulating layer (21a and 21b) may include a photosensitive insulating material such as a photoimageable dielectric (PID) resin. In some example embodiments, the at least one first insulating layer (21a and 21b) may include a resin mixed with an inorganic filler, for example, an Ajinomoto build-up film (ABF). In some example embodiments, the at least one first insulating layer (21a and 21b) may include a prepreg, a flame retardant (FR-4), or bismaleimide triazine (BT). The plurality of first insulating layers (21a and 21b) may contain the same or different materials, and a boundary therebetween may not be distinguished, depending on materials, processes, or the like forming each layer.

The at least one first wiring layer (22a and 22b) and the wiring vias 23a and 23b may form electrical paths. The at least one first wiring layer (22a and 22b) may be arranged in a linear shape on an X-Y plane. The wiring vias 23a and 23b are illustrated as filled via structures of which interiors are completely filled with a conductive material, but the wiring vias 23a and 23b are not limited thereto. For example, the wiring vias 23a and 23b may have a conformal via shape in which a metal material is formed along an internal wall of a via hole. At least one first wiring layer (22a and 22b) and wiring vias 23a and 23b may include a conductive material, and may include, for example, copper (Cu), aluminum (Al), silver (Ag), tin (Sn), gold (Au), nickel (Ni), lead (Pb), titanium (Ti), or alloys thereof.

The semiconductor chip 52 may be disposed to overlap the wiring structure (20a and 20b) in the stacking direction (e.g., Z-direction) of the wiring structure (20a and 20b). For example, the semiconductor chip 52 may be disposed above the wiring structure (20a and 20b), and may be electrically connected to the at least one first wiring layer (22a and 22b). For example, the semiconductor chip 52 may have a structure in which integrated circuits are formed on a lower surface of a semiconductor substrate formed based on a silicon wafer, may have a back-end-of-line (BEOL) stacked below the circuits, and may have connection pads formed of a conductive material stacked below the BEOL. Silicon in the silicon wafer may be replaced with a different semiconductor material such as germanium (Ge), gallium arsenide (GaAs), or the like.

For example, the semiconductor chip 52 may include a logic semiconductor chip and/or a memory semiconductor chip. The logic semiconductor chip may be a microprocessor, and may be, for example, a central processing unit (CPU), a graphics processing unit (GPU), a field programmable gate array (FPGA), an application processor (AP), a digital signal processor, a cryptographic processor, a controller, or an application specific integrated circuit (ASIC). The memory semiconductor chip may be a volatile memory such as a dynamic random access memory (DRAM), a static random access memory (SRAM), or the like, or a non-volatile memory such as a flash memory or the like.

For example, the semiconductor chip 52 may be provided as a plurality of semiconductor chips 52, and an interposer 51 may be disposed between the plurality of semiconductor chips 52 and the wiring structure (20a and 20b). One semiconductor chip among the plurality of semiconductor chips 52 or an additional semiconductor chip may be electrically connected to the at least one first wiring layer (22a and 22b). A chip encapsulant 55 may encapsulate the plurality of semiconductor chips 52. For example, a portion of the plurality of semiconductor chips 52 may be a logic semiconductor chip, and a different portion of the plurality of semiconductor chips 52 may be a memory semiconductor chip. In some example embodiments, a portion of the plurality of semiconductor chips 52 may be a power management integrated circuit (PMIC).

For example, the interposer 51 may have a structure in which at least one redistribution layer and at least one redistribution insulating layer are alternately stacked, and a combination structure 50 of the interposer 51, the plurality of semiconductor chips 52, and the chip encapsulant 55 may be a fan-out wafer level package or a fan-out panel level package. For example, the plurality of semiconductor chips 52 may be formed on an upper surface of the interposer 51 using a flip-chip bumping method, a direct pad bonding method, a wire bonding method, a post formation method, or a hybrid bonding method.

For example, the combination structure 50 of the interposer 51, the plurality of semiconductor chips 52, and the chip encapsulant 55 may be disposed on an upper surface of the wiring structure (20a or 20b) through at least a portion of bumps 61, UBMs 62a or 62b, and pads 22aP or 22bP using a flip chip ball grid array (FCBGA) method. For example, the bumps 61 may have a ball shape or a pillar shape, and may include solder containing tin (Sn) or an alloy containing tin (Sn) (Sn—Ag—Cu). The bumps 61 may have a relatively low melting point, compared to other metal materials, and may thus be connected to and fixed to the UBMs 62a and 62b by a thermal compression bonding (TCB) process or a reflow process. The UBMs 62a and 62b may be under bump metallurgy, and may be disposed between the pads 22aP and 22bP and the bumps 61. The pads 22aP and 22bP may be a portion having a relative great width on the at least one first wiring layer (22a and 22b), may have a circular shape or a polygonal shape, and may be coupled to one of the wiring vias 23a and 23b to be formed by a semi additive process (SAP) or a modified SAP (MSAP).

The second insulating layer 31 may be arranged to overlap the wiring structure (20a and 20b) in the stacking direction (e.g., Z-direction) of the wiring structure (20a and 20b), and may provide a cavity. The second insulating layer 31 may be disposed between upper and lower portions of the plurality of first insulating layers (21a and 21b), and may be disposed between upper and lower portions of the plurality of first wiring layers (22a and 22b). For example, the second insulating layer 31 may correspond to a core of the printed circuit board, and may be thicker than each of the plurality of first insulating layers (21a and 21b), or may have stronger rigidity than each of the plurality of first insulating layers (21a and 21b). Therefore, the second insulating layer 31 may support the wiring structure (20a and 20b), thereby reducing possibility of warpage of the wiring structure (20a and 20b). For example, the second insulating layer 31 may be formed based on a copper clad laminate (CCL) or a detachable copper foil (DCF).

The inductor 10 may be disposed in the cavity of the second insulating layer 31, and may be electrically connected to the semiconductor chip 52. Therefore, the inductor 10 may provide inductance to the semiconductor chip 52. Because the inductor 10 may be disposed in the cavity of the second insulating layer 31, a horizontal area of the wiring structure (20a and 20b) may not expand by adding the inductor 10. Therefore, the semiconductor package PGK1 may have an overall more compressed structure, and a large amount of inductance may be used, as compared to an overall size of the semiconductor package PGK1. Use of the large amount of inductance may lead to improved signal performance (e.g., signal integrity, power integrity, or the like).

The encapsulant 35 may encapsulate the inductor 10. Therefore, the inductor 10 may be stably placed in the cavity of the second insulating layer 31, and an electrical connection path to the semiconductor chip 52 may be stably formed. For example, a portion of the encapsulant 35 may form at least one layer between the second insulating layer 31 and the wiring structure (20a and 20b), and a remaining portion of the encapsulant 35 may be embedded in the cavity of the second insulating layer 31 to entirely occupy a space not occupied by the inductor 10. For example, each of the encapsulant 35 and the chip encapsulant 55 may contain a molding material such as an epoxy molding compound (EMC). A material that may be respectively contained in the encapsulant 35 and the chip encapsulant 55 is not limited to the molding material, and may also contain an insulating material that may have similar protective properties or higher ductility, as compared to the molding material. For example, the insulating material may be a build-up film (e.g., an Ajinomoto build-up film (ABF)), may be a thermosetting resin such as an epoxy resin, or a thermoplastic resin such as polyimide, and may be an insulating material of the at least one first insulating layer (21a and 21b) to which an inorganic filler and/or a glass fiber is appropriately added

The lead-out pillar 13a may extend from one surface (e.g., a second surface 102) of the inductor 10 facing the wiring structure (20a and 20b), and may electrically connect the inductor 10 and the semiconductor chip 52. Therefore, because an electrical connection path between the inductor 10 and the semiconductor chip 52 may be shortened, series equivalent resistance of the electrical connection path may decrease. Therefore, energy loss in a process in which the inductor 10 provides inductance to the semiconductor chip 52 may be reduced.

For example, the lead-out pillar 13a may be formed in a similar manner to the wiring vias 23a and 23b, and a portion (a lower portion) of the lead-out pillar 13a may pass through a portion of the encapsulant 35, and a different portion (an upper portion) of the pillar 13a may pass through at least one first insulating layer 21a. because a vertical extension length of the wiring vias 23a and 23b may be shorter than a horizontal extension length of at least one first wiring layer 22a, an electrical connection path of the lead-out pillar 13a may be shortened.

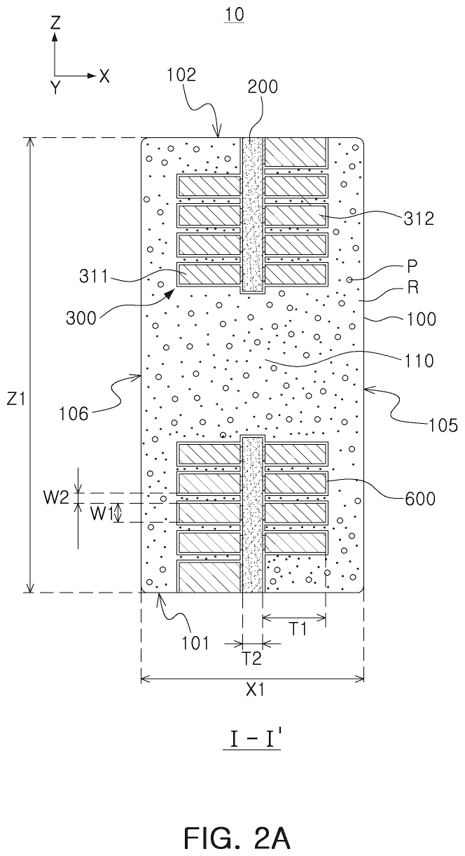

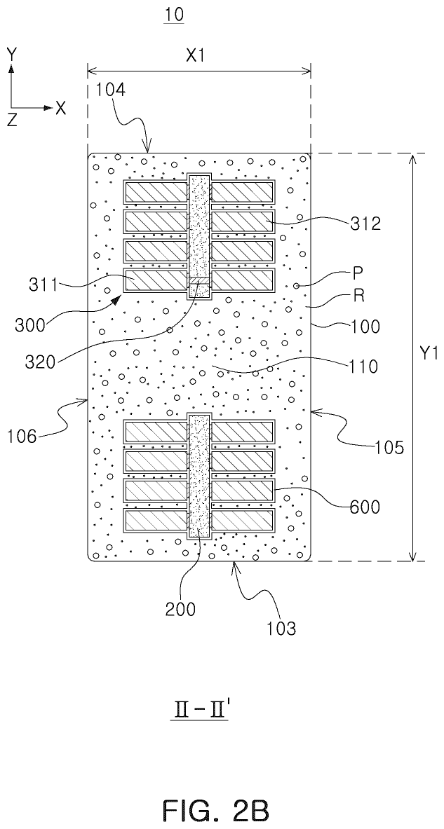

A cross-section (I-I′) in FIG. 2A is a cross-section obtained by cutting the inductor 10 of FIG. 1 from I to I′ in the X-Z plane, and a cross-section (II-II′) in FIG. 2B is a cross-section obtained by cutting the inductor 10 of FIG. 1 from II to II′ in the X-Y plane.

Referring to FIGS. 1, 2A, and 2B, the inductor 10 may include an insulating body 100, and a coil portion 300 disposed in the insulating body 100 and arranged to output a magnetic field in a direction (e.g., X-direction), different from the stacking direction (e.g., Z-direction) of the wiring structure (20a and 20b). The coil portion 300 may have a shape surrounding a direction (e.g., X-direction) in which a first coil pattern 311 and/or a second coil pattern 312 of the coil portion 300 output a magnetic field, and the surrounding shape may be a shape wound by at least one turn.

In some example embodiments, the insulating body 100 may have a first surface 101 and a second surface 102, facing the wiring structure (20a and 20b) and opposing each other, a third surface 103 and a fourth surface 104, facing the second insulating layer 31 and opposing each other, and a fifth surface 105 and a sixth surface 106, facing the second insulating layer 31 and opposing each other, and a distance (Z1) between the first and second surfaces 101 and 102 may be greater than a distance (Y1) between the third and fourth surfaces 103 and 104, and may be greater than a distance (X1) between the fifth and sixth surfaces 105 and 106.

Due to a magnetic field direction (e.g., X-direction) or a relationship between the distances (X1, Y1, and Z1), a surface from which the coil portion 300 is most efficiently drawn (e.g., having the shortest lead-out length or advantageous for forming a lead-out pattern), among the first to sixth surfaces (101, 102, 103, 104, 105, and 106), may be the second surface 102 and/or the first surface 101. As inductance of the coil portion 300 increases or equivalent series resistance of the coil portion 300 decreases, the second surface 102 and/or the first surface 101 may be more advantageous for the coil portion 300 to be lead-out.

A general inductor component having a large amount of inductance or a small amount of equivalent series resistance may be implemented to output a magnetic field in the Z-direction or have the shortest thickness in the Z-direction. Therefore, because a portion of surfaces of the inductor component has a structure covered by a conductive structure such as an electrode or a terminal, the general inductor component may form an electrical connection path to an outside by the conductive structure. Because a length for this structure to form the electrical connection path may be relatively long, energy loss in a process of providing inductance by the inductor component may increase, and there may be a limitation in increasing signal performance (e.g., signal integrity, power integrity, or the like).

At least one of the second surface 102 or the first surface 101 of the insulating body 100 of the inductor 10 of the semiconductor package PGK1 according to an example embodiment may not be covered by a conductive structure such as an electrode or a terminal. Therefore, a region not overlapping the lead-out pillar 13a on one surface (e.g., the second surface 102) of the insulating body 100 facing the wiring structure 20a may be in direct contact with the encapsulant 35 or the at least one first insulating layer 21a. An area in direct contact with the encapsulant 35 or the at least one first insulating layer 21a in the region on the one surface (e.g., the second surface 102) of the insulating body 100 facing the wiring structure 20a and not overlapping the lead-out pillar 13a may be greater than an area of a region on the one surface (e.g., the second surface 102) of the insulating body 100 facing the wiring structure 20a and overlapping the lead-out pillar 13a, or may exceed half of an area of the one surface (e.g., the second surface 102) of the insulating body 100 facing the wiring structure 20a.

Therefore, a semiconductor package PGK1 according to an example embodiment may efficiently reduce loss of energy in a process of providing inductance by an inductor 10, and may efficiently increase signal performance (e.g., signal integrity, power integrity, or the like), even by using the inductor 10 having a large amount of inductance or a small amount of equivalent series resistance, without an increase in horizontal area by addition of the inductor 10.

The insulating body 100 may include magnetic powder particles P and an insulating resin R, and may have thus higher permeability than the encapsulant 35. For example, the insulating body 100 may be formed by stacking and then curing at least one magnetic composite sheet including the insulating resin R and the magnetic powder particles P dispersed in the insulating resin R.

The magnetic powder particles P may be magnetic metal powder particles or ferrite powder particles. The magnetic metal powder particles may include any at least one selected from the group consisting of iron (Fe), silicon (Si), chromium (Cr), cobalt (Co), molybdenum (Mo), aluminum (Al), niobium (Nb), copper (Cu), and nickel (Ni). For example, the magnetic metal powder particles may be at least one of a pure iron powder particle, an Fe—Si-based alloy powder particle, an Fe—Si—Al-based alloy powder particle, an Fe—Ni-based alloy powder particle, an Fe—Ni—Mo-based alloy powder particle, an Fe—Ni—Mo—Cu-based alloy powder particle, an Fe—Co-based alloy powder particle, an Fe—Ni—Co-based alloy powder particle, an Fe—Cr-based alloy powder particle, an Fe—Cr—Si-based alloy powder particle, an Fe—Si—Cu—Nb-based alloy powder particle, an Fe—Ni—Cr-based alloy powder particle, or an Fe—Cr—Al-based alloy powder particle. The magnetic metal powder particles may be amorphous or crystalline. For example, the magnetic metal powder particles may be amorphous Fe—Si—B—Cr-based alloy powder particles, but are not necessarily limited thereto. The ferrite powder particles may be, for example, at least one of a spinel-type ferrite powder particle such as an Mg—Zn-based ferrite powder particle, an Mn—Zn-based ferrite powder particle, an Mn—Mg-based ferrite powder particle, a Cu—Zn-based ferrite powder particle, an Mg—Mn—Sr-based ferrite powder particle, an Ni—Zn-based ferrite powder particle, or the like, a hexagonal-type ferrite powder particle such as a Ba—Zn-based ferrite powder particle, a Ba—Mg-based ferrite powder particle, a Ba—Ni-based ferrite powder particle, a Ba—Co-based ferrite powder particle, a Ba—Ni—Co-based ferrite powder particle, or the like, a garnet-type ferrite powder particle such as a Y-based ferrite powder particle or the like, or an Li-based ferrite powder particle. The ferrite and magnetic metal powder particles may have an average diameter of about 0.1 μm to 30 μm, respectively, but are not limited thereto.

The insulating resin R may include epoxy, polyimide, a liquid crystal polymer, or the like, alone or in combination, but is not limited thereto.

The insulating body 100 may include a support member 200, and a core 110 passing through the coil portion 300, which will be described later. The core 110 may be formed by filling a through-hole of the coil portion 300 with at least a portion of a magnetic composite sheet in a process of stacking and curing the magnetic composite sheet, but is not limited thereto.

The coil portion 300 may include the first and second coil patterns 311 and 312, and the inductor 10 may further include the support member 200 disposed between the first and second coil patterns 311 and 312, and further include a coil via 320 passing through the support member 200 to electrically connect the first and second coil patterns 311 and 312.

The support member 200 may be formed of an insulating material containing a thermosetting insulating resin such as epoxy resin, a thermoplastic insulating resin such as polyimide, or a photosensitive insulating resin, or may be formed of an insulating material in which the insulating resin is impregnated with a reinforcing material such as a glass fiber or an inorganic filler. For example, the support member 200 may be formed of an insulating material such as a copper clad laminate (CCL), a prepreg, an Ajinomoto build-up film (ABF), FR-4, a bismaleimide triazine (BT) film, a photo imagable dielectric (PID) film, or the like, but is not limited thereto. The inorganic filler may use at least one selected from the group consisting of silica (SiO₂), alumina (Al₂O₃), silicon carbide (SiC), barium sulfate (BaSO₄), talc, clay, a mica powder particle, an aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃). When the support member 200 is formed of an insulating material including a reinforcing material, the support member 200 may provide better rigidity. When the support member 200 is formed of an insulating material not including a glass fiber, the support member 200 may be advantageous in entirely reducing a thickness of the coil portion 300. When the support member 200 is formed of an insulating material including a photosensitive insulating resin, the number of processes for forming the coil portion 300 may be reduced, which may be advantageous in reducing production costs and may allow formation of a fine via. A thickness T2 of the support member 200 may be greater than 20 μm and less than 40 μm, more specifically 25 μm or more and 35 μm or less, but is not limited thereto.

For example, at least a portion of the coil via 320 may be formed by electroplating. For example, the coil via 320 may include a seed layer formed on an internal wall of a via hole passing through the support member 200, and an electroplating layer filling the via hole in which the seed layer is formed. The seed layer of the coil via 320 and a seed layer for forming the first and second coil patterns 311 and 312 may be formed together in the same process, and may be integrated with each other, or may be formed in different processes to form a boundary between the two. The coil via 320 may include a conductive material such as copper (Cu), aluminum (Al), silver (Ag), tin (Sn), gold (Au), nickel (Ni), lead (Pb), titanium (Ti), chromium (Cr), molybdenum (Mo), an alloy thereof, or the like. For example, the seed layer may be formed by electroless plating or sputtering.

For example, each of the first and second coil patterns 311 and 312 of the coil portion 300 may be formed by electroplating (e.g., copper plating) on the seed layer, and may be formed by competition growing in anisotropic plating. Depending on characteristics of the competition growing in anisotropic plating, a thickness T1 of each of the first and second coil patterns 311 and 312 may be greater than a width W1. The width W1 may be greater than an interval W2. Because the width W1 may be limited by the number of turns of each of the first and second coil patterns 311 and 312, equivalent series resistance of each of the first and second coil patterns 311 and 312 may decrease due to an increase in thickness T1. Therefore, when the thickness T1 is greater than the width W1, the inductor 10 may have a large amount of inductance and/or a small amount of equivalent series resistance.

Depending on the design, the inductor 10 may further include an insulating film 600 in direct contact between the coil portion 300 and the insulating body 100. The insulating film 600 may be used to insulate the first and second coil patterns 311 and 312 from the body 100, and may include a known insulating material such as parylene or the like. Any insulating material included in the insulating film 600 is possible, and there is no particular limitation thereto. The insulating film 600 may be formed by a process such as vapor deposition or the like, but is not limited thereto, and may be formed by stacking an insulating film on both surfaces of the support member 200. In the former case, the insulating film 600 may be formed as a conformal film along surfaces of the support member 200 and the first and second coil patterns 311 and 312. In the latter case, the insulating film 600 may be formed to fill a space between adjacent turns of the first and second coil patterns 311 and 312. Therefore, a thickness of the insulating film 600 is not particularly limited. In the present inventive concepts, the insulating film 600 may be an optional configuration. Therefore, when the insulating body 100 secures sufficient insulation resistance under operating conditions of a coil component according to the present embodiment, the insulating film 600 may be omitted.

Because the support member 200 may be disposed in a central portion of the inductor 10, the first and second coil patterns 311 and 312 may be exposed at points biasedly located toward the other surface and one surface from central portions of the first and second surfaces 101 and 102 of the insulating body 100, respectively. In other words, the first and second coil patterns 311 and 312 may be exposed at points on the first and second surfaces 101 and 102 of the insulating body 100 that are offset from central portions thereof, respectively. Therefore, the lead-out pillar 13a may extend from a position laterally biased (or offset) from a center of the one surface (e.g., the second surface 102) of the insulating body 100 in the Z-direction.

A semiconductor package PGK1 according to an example embodiment may further include an additional lead-out pillar 13b extending from the other surface (e.g., the first surface 101) of the insulating body 100 of the inductor 10 opposing the one surface (e.g., the second surface 102) of the insulating body 100 of the inductor 10 from which the lead-out pillar 13a extends. The lead-out pillar 13a and the additional lead-out pillar 13b may extend in opposite directions at positions bilaterally biased (e.g., laterally offset) from centers of the one surface (e.g., the second surface 102) and the other surface (e.g., the first surface 101) of the insulating body 100, respectively.

The additional lead-out pillar 13b may provide an electrical connection path between the inductor 10 and a structure (e.g., a printed circuit board, a semiconductor chip, or the like) connected to a lower side of the semiconductor package PGK1, and a length of the electrical connection path may be effectively reduced. For example, a portion of the additional lead-out pillar 13b may pass through a portion of the encapsulant 35, and a different portion of the additional lead-out pillar 13b may pass through the at least one first insulating layer 21b.

Referring to FIG. 1, a semiconductor package PGK1 according to an example embodiment may further include at least one of at least one second wiring layer 32, at least one through-via 33, a cover layer (40a and 40b), or a capacitor component 70. A combination structure 30 of the second insulating layer 31, the at least one second wiring layer 32, and the at least one through-via 33 may be disposed between upper and lower portions of the wiring structure (20a and 20b).

The at least one second wiring layer 32 may be disposed on an upper surface and/or a lower surface of the second insulating layer 31, and may be electrically connected to the at least one first wiring layer (22a and 22b). For example, the at least one second wiring layer 32 may be formed by etching a portion of a release copper foil layer of a copper clad laminate (CCL).

The at least one through-via 33 may pass through the second insulating layer 31, and may be electrically connected to the at least one second wiring layer 32. For example, the at least one through-via 33 may include a plating layer 33a plated on a surface of a through-hole 33b, and may be provided as a conformal via, but is not limited thereto.

The cover layer (40a and 40b) may cover an upper surface and a lower surface of the wiring structure (20a and 20b), and may include a plurality of openings for providing electrical connection paths to an outside of the wiring structure (20a and 20b). For example, the cover layer (40a and 40b) may be formed as a solder resist or a dry film resist, and may include an insulating material, different from the first and second insulating layers 21a, 21b, and 31. For example, the openings may be formed by a patterning method (e.g., a photo-lithography method).

The capacitor component 70 may be a component providing capacitance, such as a multilayer ceramic capacitor (MLCC), and may be mounted on an upper surface of the wiring structure (20a and 20b). For example, unlike the inductor 10, the capacitor component 70 may have a structure in which external electrodes 72 are formed on side surfaces of a dielectric body 71, may be electrically connected to the wiring structure (20a and 20b) through the external electrodes 72 and bumps 73, and may provide capacitance to the semiconductor chip 52.

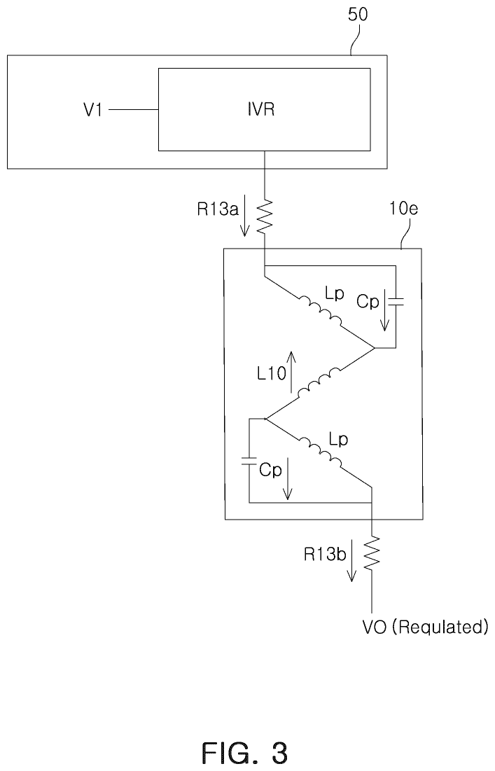

Referring to FIG. 3, a structure (50) including a semiconductor chip may include a voltage regulator (an integrated voltage regulator, IVR), and the voltage regulator (IVR) may generate an output voltage VO based on an input voltage V1. The output voltage VO may have a relatively stable value, as compared to the input voltage V1, and as inductance L10 of an inductor 10e increases, the output voltage VO may be more stabilized.

Because the lead-out pillar 13a and the additional lead-out pillar 13b in FIG. 1 may be shortened, equivalent series resistance (R13a and R13b) of the lead-out pillar 13a and the additional lead-out pillar 13b in FIG. 1 may also be reduced.

Because at least one of a second surface or a first surface of an insulating body of the inductor 10e may not be covered by a conductive structure such as an electrode or a terminal, the equivalent series resistance (R13a and R13b) may advantageously be made smaller, and parasitic capacitance Cp of the inductor 10e may also be reduced. Parasitic capacitance Cp may be formed by capacitance coupling between a conductive structure such as an electrode or a terminal and a coil portion, but the inductor 10e may not be covered by a conductive structure such as an electrode or a terminal. The parasitic capacitances Cp may be connected in parallel to some of inductance Lp of the inductor 10e, and may affect accuracy of the output voltage VO. For example, a semiconductor package according to an example embodiment may further improve signal performance (e.g., signal integrity, power integrity, or the like) by reducing the parasitic capacitance Cp.

The voltage regulator (IVR) may be replaced with a circuit (e.g., radio frequency circuit, DC-DC converter circuit, or the like) needing a large amount of inductance L10, a small amount of equivalent series resistance (R13a and R13b), and/or a small amount of parasitic capacitance Cp, according to a design.

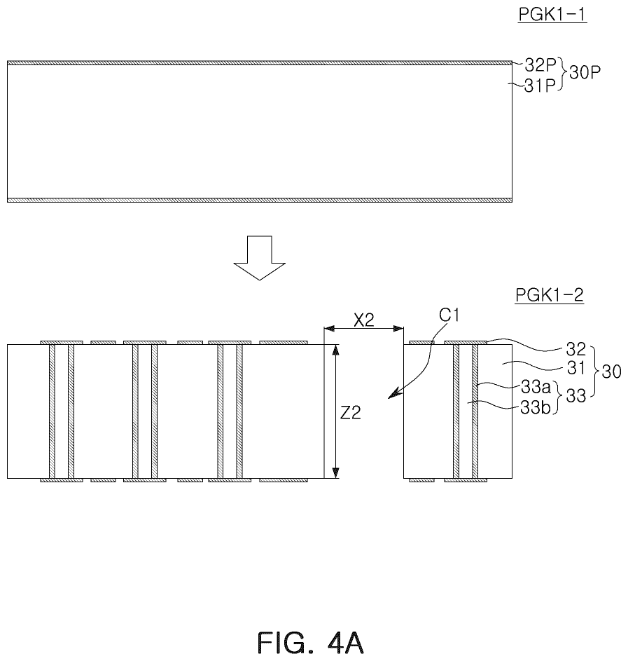

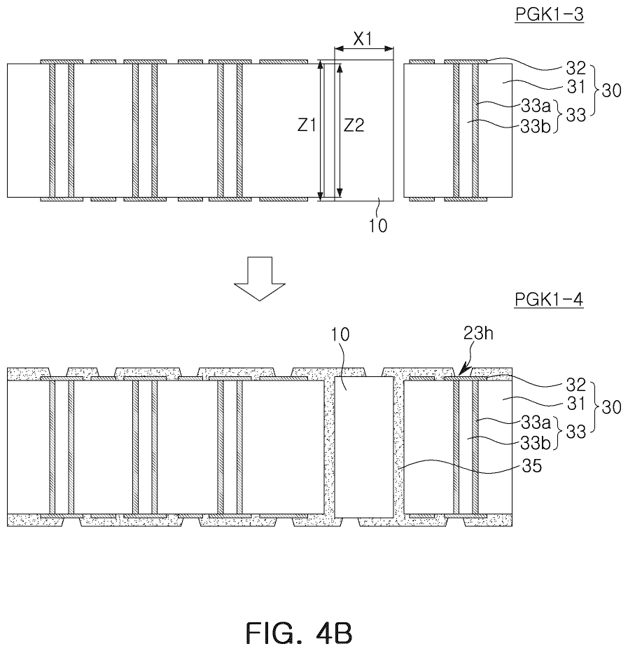

Referring to FIGS. 4A and 4B, a semiconductor package according to an example embodiment may be manufactured by sequentially passing through a first state PGK1-1, a second state PGK1-2, a third state PGK1-3, and a fourth state PGK1-4 to prepare the semiconductor package PGK-1 of FIG. 1, but example embodiments are not limited thereto.

The first state PGK1-1 of the semiconductor package may have a structure 30P in which second wiring layers 32P are formed on upper and lower surfaces of a second insulating layer 31P. For example, the structure 30P may be a copper clad laminate (CCL) or a detachable copper foil (DCF).

The second state PGK1-2 of the semiconductor package may have a structure in which second wiring layers 32, in which portions of the second wiring layers 32P are etched, are disposed on upper and lower surfaces of a second insulating layer 31, and may have a structure in which a cavity C1 and through-vias 33 are formed in the second insulating layer 31. For example, the cavity C1 may be formed by a process of irradiating a laser in a vertical direction, a process of colliding multiple particles, or a process of drilling.

The third state PGK1-3 of the semiconductor package may have a structure in which the inductor 10 is manufactured separately and disposed in the cavity of the second insulating layer 31. In this case, a lower surface of an inductor 10, together with a lower surface of a second wiring layer 32 disposed on a lower surface of the second insulating layer 31, may form one plane. The one plane may be a plane of a structure supporting the semiconductor package in the third state PGK1-3.

Therefore, a distance Z1 between first and second surfaces of the inductor 10 may be greater than a thickness Z2 of the second insulating layer 31. Because the first and second surfaces of the inductor 10 are not covered by a conductive structure such as an electrode or a terminal, the distance Z1 between first and second surfaces of an insulating body of the inductor 10 may be greater than the thickness Z2 of the second insulating layer 31. As the distance Z1 between the first and second surfaces increases, inductance of the inductor 10 may increase, and a length of a lead-out pillar may be shortened. A distance X1 between fifth and sixth surfaces of the inductor 10 may also be shorter than a length X2 of the cavity C1 in the X-direction.

The fourth state PGK1-4 of the semiconductor package may have a structure in which an encapsulant 35 is further formed, and may have a structure in which openings are formed on upper and lower surfaces of the encapsulant 35. The openings may be formed by a patterning method (e.g., a photo-lithography method), and may provide vertical electrical connection paths between the inductor 10 and the second wiring layers 32. The electrical connection paths may be a portion of the lead-out pillar or a portion of wiring vias. Thereafter, a wiring structure may be built up on the upper and lower surfaces of the encapsulant 35, and a semiconductor chip may be placed on one surface of the wiring structure.

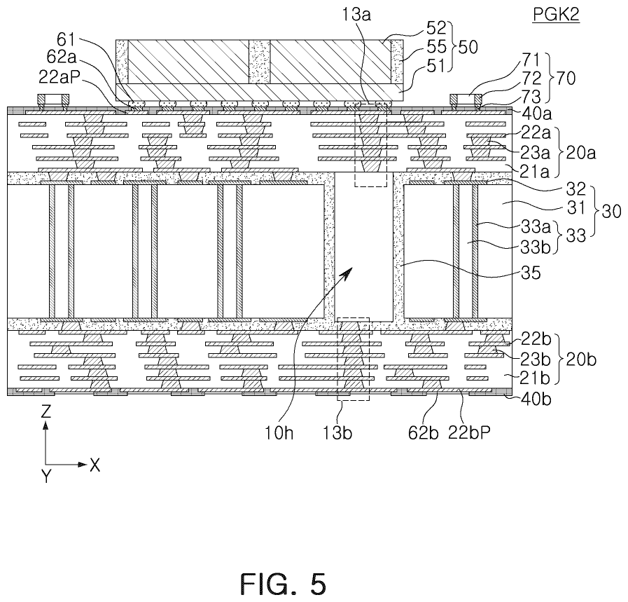

Referring to FIG. 5, a semiconductor package PGK2 according to an example embodiment may have a structure in which an upper surface of an inductor 10h is in direct contact with at least one first insulating layer 21a. A distance between first and second surfaces of the inductor 10h may be longer than a distance between the first and second surfaces of the inductor 10 in FIG. 1. In some example embodiments, the inductor 10h may be in direct contact with the at least one first insulating layer 21a, as a distance between upper and lower surfaces of an encapsulant 35 decreases.

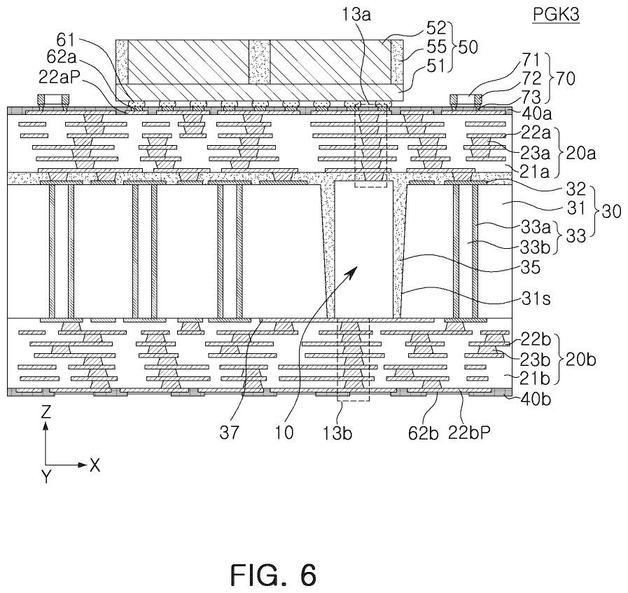

Referring to FIG. 6, a semiconductor package PGK3 according to an example embodiment may further include a conductive support layer 37 directly contacting the other surface (e.g., a first surface) of an insulating body of an inductor 10 facing one surface (e.g., a second surface) of the insulating body of the inductor 10 to which a lead-out pillar 13a extends, and directly contacting a second insulating layer 31. The conductive support layer 37 may be formed in a similar manner to first and second wiring layers 22b and 32.

For example, in a wiring structure (20a and 20b), a lower portion may be formed earlier than an upper portion, and the wiring structure (20a and 20b) may be formed earlier than a cavity of the second insulating layer 31. Thereafter, the cavity of the second insulating layer 31 may be formed from the top to the bottom, and the conductive support layer 37 may serve as a stopper in a process of forming the cavity. In this case, a side surface 31s of the cavity may be inclined with respect to a side surface of the inductor 10 (e.g., fifth and sixth surfaces). Thereafter, the encapsulant 35 may be formed from a lower surface of the second insulating layer 31 in an upward direction, and the wiring structure (20a and 20b) may be formed on the encapsulant 35.

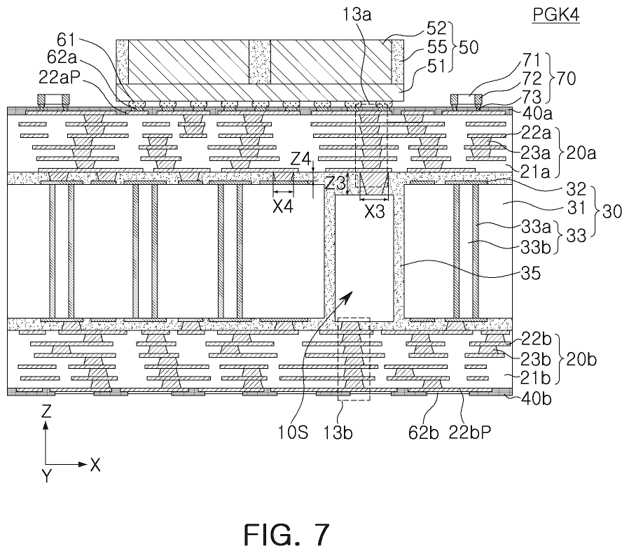

Referring to FIG. 7, a semiconductor package PGK4 according to an example embodiment may have a structure in which an upper surface of an inductor 10s is located on a lower level than an upper surface of a second insulating layer 31. Alternatively, a width X3 of a portion of a lead-out pillar 13a passing through a portion of an encapsulant 35 may be greater than a width X4 of each wiring via 23a. A length Z3 of a portion of the lead-out pillar 13a passing through a portion of the encapsulant 35 may be greater than a length Z4 of each of the wiring vias 23a. Therefore, equivalent series resistance of the lead-out pillar 13a may be further reduced.

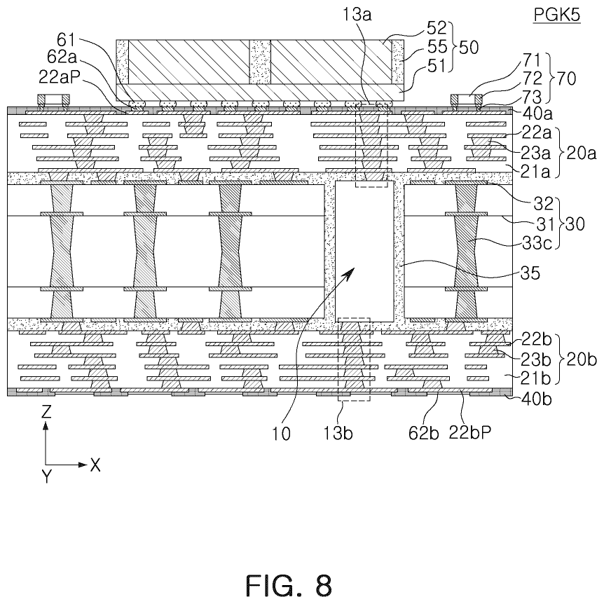

Referring to FIG. 8, a semiconductor package PGK5 according to an example embodiment may have a structure in which second insulating layers 31 are stacked, and may have a structure in which through-vias 33c are completely filled with conductive materials. For example, the conductive materials may be formed by filling with conductive paste as well as plating.

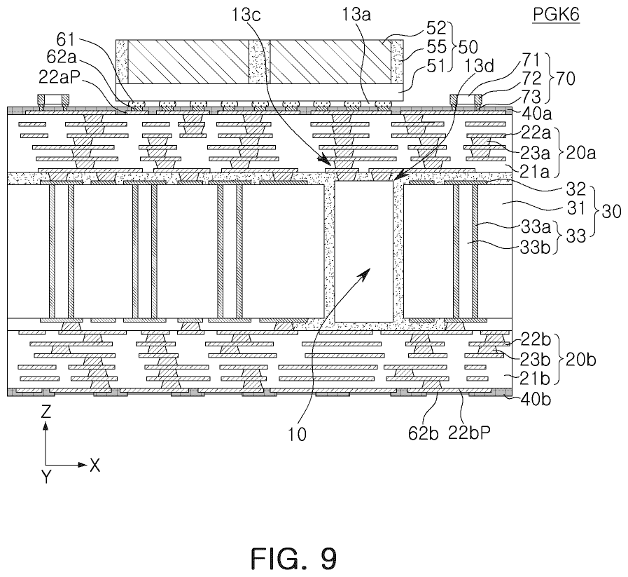

Referring to FIG. 9, a semiconductor package PGK6 according to an example embodiment may have a structure in which a plurality of lead-out pillars 13c and 13d spaced apart from each other are formed on an upper surface of an inductor 10. One of the plurality of lead-out pillars 13c and 13d may be electrically connected to a semiconductor chip 52, and the other one of the plurality of lead-out pillars 13c and 13d may be electrically connected to a capacitor component 70, or may be electrically connected to through-vias 33. For example, first and second coil patterns of a coil portion of the inductor 10 may be exposed to an upper surface of an insulating body, and the first coil pattern may be wound half a turn less or more, as compared to the first coil pattern 311 in FIGS. 2A and 2B.

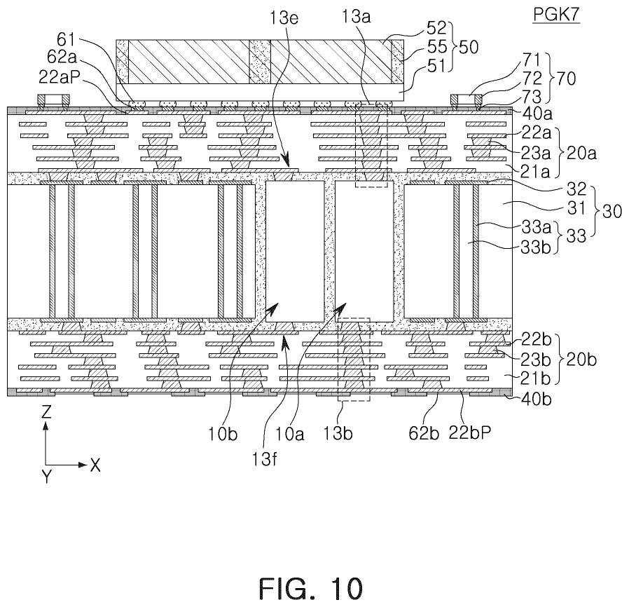

Referring to FIG. 10, a semiconductor package PGK7 according to an example embodiment may further include an additional inductor 10b disposed in a cavity, and an inductor 10a and the additional inductor 10b may be arranged to output a magnetic field in a same direction (e.g., X-direction). For example, a combination of inductor 10a and the additional inductor 10b may be a transformer or a balun. In some example embodiments, the inductor 10a and the additional inductor 10b may be connected in series to boost inductance.

The additional inductor 10b may be implemented in substantially the same manner to the inductor 10a (but inductance or characteristics may be different), and may be connected to third and fourth lead-out pillars 13e and 13f. The third and fourth lead-out pillars 13e and 13f may also be implemented in substantially the same way as a lead-out pillar 13a and an additional lead-out pillar 13b. Because a horizontal length (e.g., X1 and Y1) of each of the inductor 10a and the additional inductor 10b may be shorter than a vertical length (e.g., Z1) thereof, mounting of the inductor 10a and the additional inductor 10b in one cavity may not have a significant impact on stability (e.g., anti-warpage performance) of the semiconductor package PGK7.

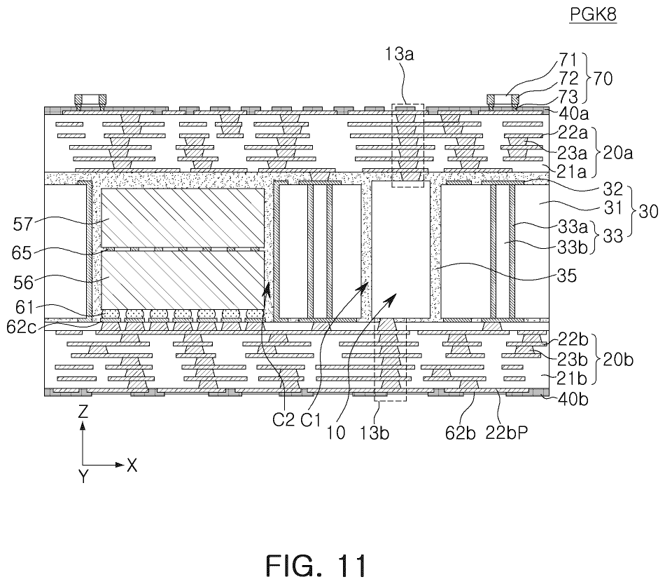

Referring to FIG. 11, a semiconductor package PGK8 according to an example embodiment may have a structure in which a second insulating layer 31 provides an additional cavity C2 and semiconductor chips 56 and 57 are disposed in the additional cavity C2. For example, the semiconductor chips 56 and 57 may be vertically connected to each other through connection pads 65, and the semiconductor chip 56 may include conductive vias passing through a semiconductor substrate of the semiconductor chip 56. The semiconductor chips 56 and 57 may be electrically connected to pads 62c through bumps 61, and the pads 62c may be electrically connected to at least one first wiring layer 22b of a wiring structure 20b.

A semiconductor package according to an example embodiment may efficiently use inductance outside of a semiconductor chip. For example, a semiconductor package according to an example embodiment may efficiently reduce loss of energy in a process of providing inductance by an inductor, and may efficiently increase signal performance (e.g., signal integrity, power integrity, or the like), even by using the inductor having a large amount of inductance or a small amount of equivalent series resistance, without an increase in horizontal area by addition of the inductor.

While some example embodiments have been illustrated and described above, it will be apparent to those skilled in the art that modifications and variations could be made without departing from the scope of the present inventive concepts as defined by the appended claims.

What is claimed is:

1. A semiconductor package comprising:
a wiring structure having an alternating structure of at least one first wiring layer and at least one first insulating layer;
a semiconductor chip overlapping the wiring structure in a stacking direction of the wiring structure;
a second insulating layer overlapping the wiring structure in the stacking direction of the wiring structure and including a cavity;
an inductor in the cavity and electrically connected to the semiconductor chip;
a lead-out pillar extending from one surface of the inductor facing the wiring structure, and electrically connecting the inductor and the semiconductor chip; and
an encapsulant encapsulating the inductor,
wherein the inductor includes an insulating body and a coil portion disposed in the insulating body, the coil portion configured to output a magnetic field in a direction, different from the stacking direction of the wiring structure, and
wherein a first region on one surface of the insulating body facing the wiring structure and not overlapping the lead-out pillar is in direct contact with the encapsulant or the at least one first insulating layer.

2. The semiconductor package of claim 1, wherein an area of the first region is greater than an area of a second region on the one surface of the insulating body and overlapping the lead-out pillar.

3. The semiconductor package of claim 1, wherein the lead-out pillar extends from a position laterally offset from a center of the one surface of the insulating body.

4. The semiconductor package of claim 1, wherein
a portion of the lead-out pillar passes through a portion of the encapsulant, and
a different portion of the lead-out pillar passes through the at least one first insulating layer.

5. The semiconductor package of claim 4, wherein
the wiring structure comprises wiring vias connected to the at least one first wiring layer and passing through the at least one first insulating layer, and
a width of the portion of the lead-out pillar passing through the portion of the encapsulant is greater than a width of each of the wiring vias.

6. The semiconductor package of claim 1, wherein the semiconductor chip comprises a voltage regulator.

7. The semiconductor package of claim 1, wherein the at least one first wiring layer includes a plurality of first wiring layers, and
the at least one first insulating layer includes a plurality of first insulating layers,
wherein the second insulating layer is between upper and lower portions of the plurality of first wiring layers and is between upper and lower portions of the plurality of first insulating layers.

8. The semiconductor package of claim 7, wherein a thickness of the second insulating layer is greater than a thickness of each of the plurality of first insulating layers.

9. The semiconductor package of claim 7, further comprising:
an additional lead-out pillar extending from the other surface of the insulating body of the inductor opposing the one surface of the insulating body of the inductor from which the lead-out pillar extends,
wherein the lead-out pillar and the additional lead-out pillar extend in opposite directions at positions laterally offset from centers of the one surface and the other surface of the insulating body, respectively.

10. The semiconductor package of claim 1, wherein
the second insulating layer provides an additional cavity, and
the semiconductor chip is disposed in the additional cavity.

11. The semiconductor package of claim 1, further comprising:
an additional semiconductor chip electrically connected to the at least one first wiring layer; and
an interposer between the semiconductor chip and the wiring structure and between the additional semiconductor chip and the wiring structure.

12. The semiconductor package of claim 1, further comprising:
an additional inductor in the cavity,
wherein the inductor and the additional inductor is configured to output magnetic fields in a same direction.

13. The semiconductor package of claim 1, further comprising:
a conductive support layer directly contacting the other surface of the insulating body opposing the one surface of the insulating body from which the lead-out pillar extends, the conductive support layer directly contacting the second insulating layer.

14. The semiconductor package of claim 1, wherein the insulating body comprises magnetic powder particles and an insulating resin.

15. The semiconductor package of claim 1, wherein
the coil portion comprises a first coil pattern and a second coil pattern, and the inductor further comprises,
a support member between the first and second coil patterns, and
a coil via passing through the support member and electrically connecting the first and second coil patterns, and
in each of the first and second coil patterns, a thickness T1 is greater than a width W1.

16. The semiconductor package of claim 1, wherein
the insulating body has a first surface and a second surface facing the wiring structure and opposing each other, a third surface and a fourth surface facing the second insulating layer and opposing each other, and a fifth surface and a sixth surface facing the second insulating layer and opposing each other, and
a distance (Z1) between the first and second surfaces is greater than a distance (Y1) between the third and fourth surfaces, is greater than a distance (X1) between the fifth and sixth surfaces, and is greater than a thickness (Z2) of the second insulating layer.

17. A semiconductor package comprising:
a wiring structure having an alternating structure of at least one first wiring layer and at least one first insulating layer;
a semiconductor chip overlapping the wiring structure in a stacking direction of the wiring structure;
a second insulating layer overlapping the wiring structure in the stacking direction of the wiring structure and including a cavity;
an inductor in the cavity and electrically connected to the semiconductor chip; and
a lead-out pillar extending from one surface of the inductor facing the wiring structure and electrically connecting the inductor and the semiconductor chip,
wherein the inductor includes an insulating body and a coil portion in the insulating body,
wherein the insulating body has a first surface and a second surface facing the wiring structure and opposing each other, a third surface and a fourth surface facing the second insulating layer and opposing each other, and a fifth surface and a sixth surface facing the second insulating layer and opposing each other, and
wherein a distance (Z1) between the first and second surfaces is greater than a distance (Y1) between the third and fourth surfaces, is greater than a distance (X1) between the fifth and sixth surfaces, and is greater than a thickness (Z2) of the second insulating layer.

18. The semiconductor package of claim 17, wherein
the insulating body comprises magnetic powder particles and an insulating resin,
the coil portion comprises a first coil pattern and a second coil pattern, a thickness T1 of each of the first and second coil patterns being greater that a width W1 thereof, and
the inductor further comprises,
a support member between the first and second coil patterns, and
a coil via passing through the support member and electrically connecting the first and second coil.

19. The semiconductor package of claim 18, further comprising:
an additional lead-out pillar extending from the other surface of the insulating body of the inductor opposing the one surface of the insulating body of the inductor from which the lead-out pillar extends,
wherein the lead-out pillar and the additional lead-out pillar extend in opposite directions at positions laterally offset from centers of the one surface and the other surface of the insulating body, respectively,
the at least one first wiring layer includes a plurality of first wiring layers,
the at least one first insulating layer includes a plurality of first insulating layers,
the second insulating layer is between upper and lower portions of the plurality of first wiring layers, and is between upper and lower portions of the plurality of first insulating layers, and
a thickness of the second insulating layer is greater than a thickness of each of the plurality of first insulating layers.

20. A semiconductor package comprising:
a wiring structure having an alternating structure of at least one first wiring layer and at least one first insulating layer;
a semiconductor chip overlapping the wiring structure in a stacking direction of the wiring structure;
a second insulating layer overlapping the wiring structure in the stacking direction of the wiring structure and including a cavity;
an inductor in the cavity and electrically connected to the semiconductor chip;
a lead-out pillar extending from one surface of the inductor facing the wiring structure and electrically connecting the inductor and the semiconductor chip;
an additional lead-out pillar extending from the other surface of an insulating body of the inductor opposing the one surface of the insulating body of the inductor; and
an encapsulant encapsulating the inductor,
wherein the inductor includes the insulating body, and a coil portion in the insulating body, the coil portion configured to output a magnetic field in a direction, different from the stacking direction of the wiring structure,
the at least one first wiring layer includes a plurality of first wiring layers,
the at least one first insulating layer includes a plurality of first insulating layers,
a first portion of the lead-out pillar and a first portion of the additional lead-out pillar pass through a portion of the encapsulant,
a second portion of the lead-out pillar and a second portion of the additional lead-out pillar pass through upper and lower portions of the plurality of first insulating layers, respectively, the first portion of the lead-out pillar and the first portion of the additional lead-out pillar being different from the second portion of the lead-out pillar and the second portion of the additional lead-out pillar, respectively, and
the lead-out pillar and the additional lead-out pillar extend in opposite directions at positions laterally offset from centers of the one surface and the other surface of the insulating body, respectively.
